(19) United States
(12) Patent Application Publication
(10) Pub. No.: US 2011/0181267 A1
(43) Pub. Date: Jul. 28, 2011

(54) Test analyzer

(76) Inventor: Michael J. Distler, Kemah, TX (US)

(21) Appl. No.: 12/693,572

(22) Filed: Jan. 26, 2010

(51) Int. Cl. G01R 19/00

(52) U.S. Cl. 324/76.11

(57) ABSTRACT

A portable calibrated resistive load testing analyzer for use with an Electronic Biofeedback Stimulation Device.
Two operational modes are available.
1. Provides calibrated resistive loads in treatment mode for device testing using channel 1 output to scope.
2. Provides calibrated resistive loads in analyze mode to verify accuracy of skin resistance readings.

### FIELD OF INVENTION

The invention relates to testing equipment in the field of pain management systems, and particularly to Biofeedback Stimulation Devices.

### BACKGROUND OF THE INVENTION

Electronic Biofeedback Stimulation Devices generate electrical pulses having a peak output voltage, pulse width and pulse repetition rate. The pulses are transmitted to electrodes placed on a persons body. Biofeedback devices also measure skin resistance. Testing of these units is important to determine if the unit is functioning properly and to meet FDA testing requirements and verification of accuracy for clinical trials.

### SUMMARY OF THE INVENTION

The present invention relates to testing systems particularly for testing electronic biofeedback stimulation devices.

The present invention is realized by inserting the Biofeedback device into the cradle of the test analyzer. The external electrode probe is inserted into its mating cradle of the test analyzer. The test analyzer can then be used to make measurements of the output signal parameters of the stimulator under test by use of the internal resistive load built into the test analyzer. Also analyze mode skin resistance readings can be tested and verified for accuracy by use of the calibrated analyze test mode settings.

### BRIEF DESCRIPTION OF THE DRAWINGS

FIG. 1 is a front view of the Test Analyzer showing the overall appearance.

FIG. 2 is a block diagram of the Test Analyzer.

FIG. 3 is a schematic diagram of the Test Analyzer.

FIG. 4 is a Resistance Graph showing the relative Analyze mode reading versus resistance.

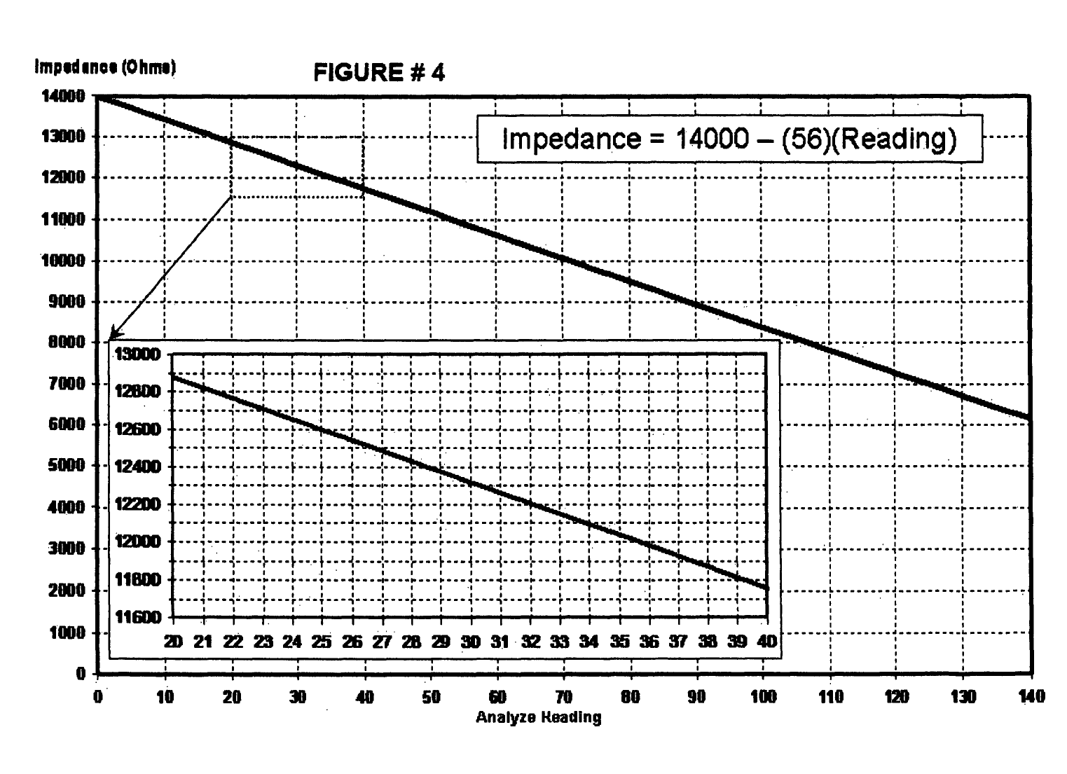

FIG. 5 is a typical output waveform measured at CH1 when using main device or CH2 when using the external probe.

FIG. 6 is a Delta Scanner® Biofeedback Stimulator designed for use with the Test Analyzer.

### DETAILED DESCRIPTION OF THE INVENTION

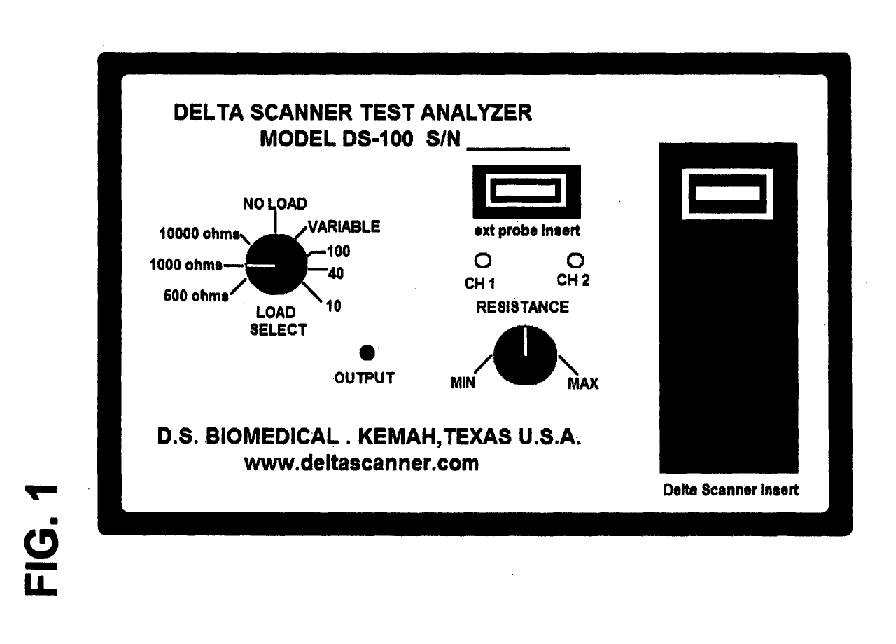

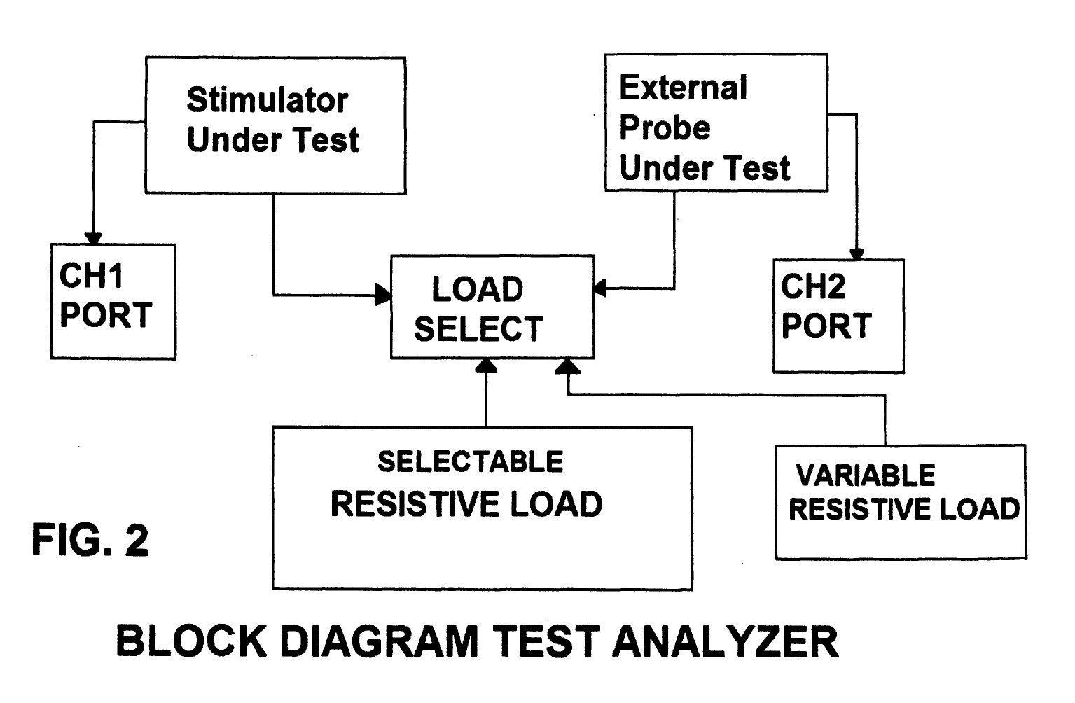

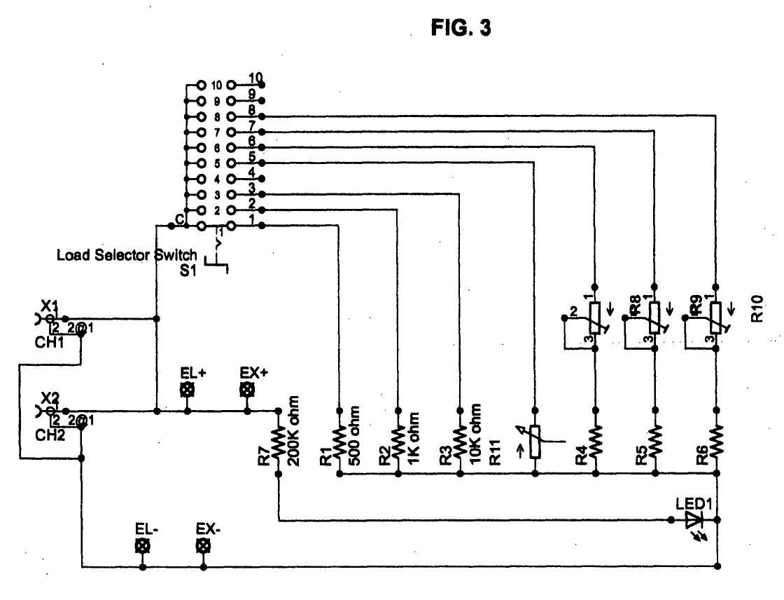

In FIG. 1, an enclosure is shown which contains the electronic circuitry of the biofeedback stimulator test analyzer. The enclosure contains a circuit board as shown in FIG. 3. In FIG. 2, the enclosure also contains a load selector switch, variable load switch, CH1 and CH2 test ports, output indicator and the Delta Scanners device cradles.

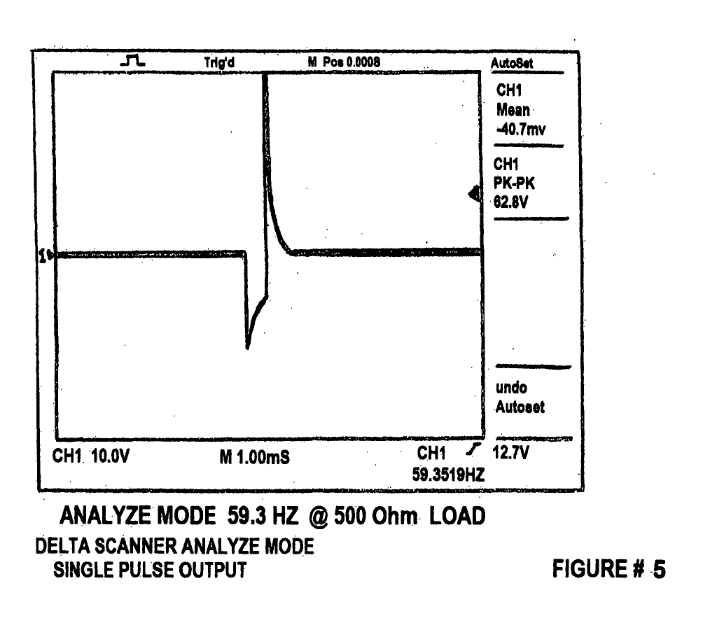

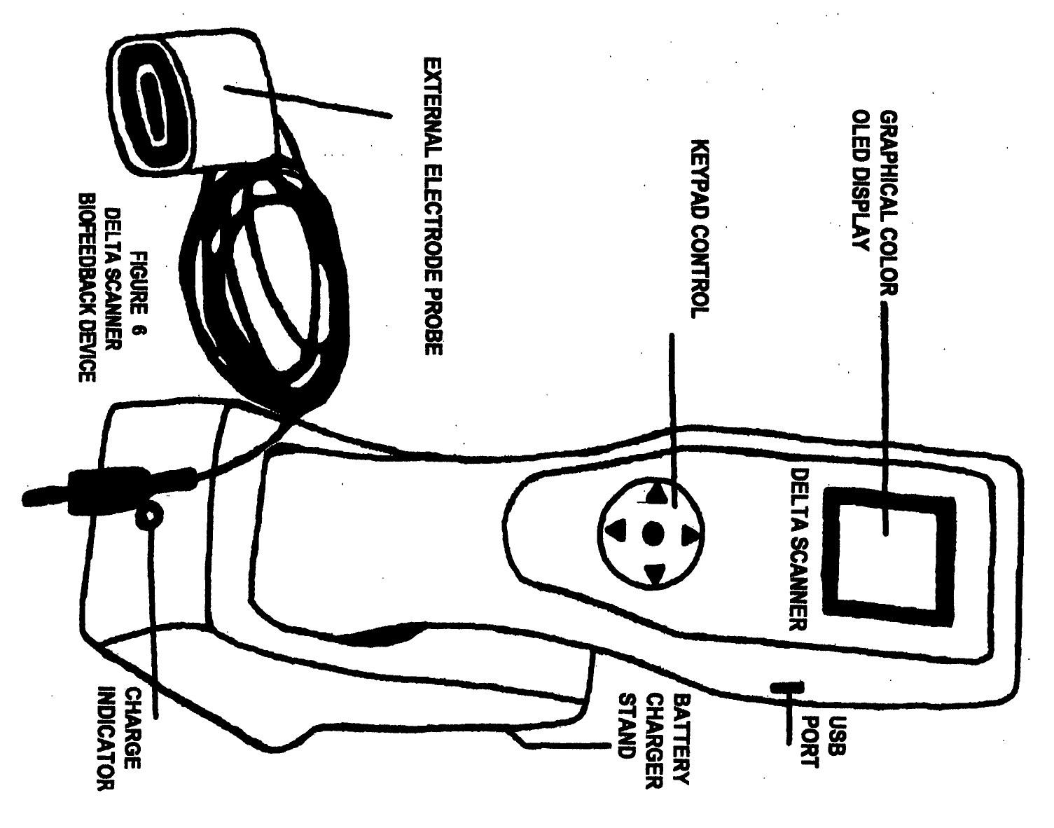

FIG. 2 shows a block diagram of the test analyzer. The biofeedback stimulator FIG. 6 is inserted into the Stimulator under test cradle, and the External probe FIG. 6 is inserted into the External probe under test cradle. The output pulse as shown in FIG. 5 is transmitted to the load select switch and then to either the selectable load or the variable load. Testing port CH 1 allows for sampling of the biofeedback stimulator output signals. Testing port CH 2 allows for sampling of the external probe signals. The test analyzer also sends back a calibrated biofeedback reading used in the analyze mode of the stimulator. This is calibrated to a known standard to verify accuracy of readings and provide a reference tool for use in clinical trial studies. It also provides for device testing requirements under F.D.A guidelines.

1. A portable test analyzer, comprised of a passive load circuit and sampling output for connection of measuring equipment. Load circuit is selectable from 500 Ohms, 1000 Ohms, 10000 Ohms and no load.

2. A portable test analyzer, comprised of two cradles to accept a biofeedback stimulator main unit and external electrode unit. The cradles contain matching electrodes with separate sampling outputs allowing for device under test measurements of the main unit or the external unit.

3. A portable test analyzer, comprised of a calibrated selectable load for verification of analyze mode skin resistance readings. Load circuit is selectable from 10, 40, 100 and variable.

4. A portable test analyzer, comprised of a calibrated reference standard at 1% accuracy for use in clinical trials verification and validation of patient studies using biofeedback stimulation devices.
